(19) United States
(12) Patent Application Publication
(10) Pub. No.: US 2025/0377217 A1
(43) Pub. Date: Dec. 11, 2025

(54) INTEGRATED CIRCUIT FOR SIGNAL PROCESSING OF A SENSOR AND METHOD FOR THE OPEN OR CLOSED LOOP CONTROLLING OF A TEMPERATURE OR OF A TEMPERATURE DISTRIBUTION IN THE CIRCUIT

(71) Applicant: Micro-Epsilon-Messtechnik Gmbh & Co. K.G., Ortenburg (DE)

(72) Inventors: Juergen ILG, Ortenburg (DE); Juergen SALLER, Wallerfing (DE); Stefan JUNGE, Passau (DE)

(21) Appl. No.: 18/877,075

(22) PCT Filed: Jul. 27, 2023
(86) PCT No.: PCT/DE2023/200157

§ 371 Date: Dec. 19, 2024

(30) Foreign Application Priority Data
Aug. 1, 2022 (DE) 10 2022 207 939.6

(51) Int. Cl. G01D 3/036; G01D 5/14

(52) U.S. Cl. CPC G01D 3/0365; G01D 5/14

(57) ABSTRACT

With respect to particularly accurate measurements even at changing temperatures with structurally simple means, an integrated circuit for signal processing of a sensor, wherein the sensor is an inductively working sensor or an eddy current sensor and wherein the circuit has electronic components and is part of an oscillating circuit, is characterized by a temperature-control device for the open- or closed-loop controlling of a temperature and/or of a temperature distribution in the circuit and/or in at least one electronic component of the circuit. Furthermore, a method is specified for the open- or closed-loop controlling of a temperature or of a temperature distribution in the circuit or in at least one electronic component of the circuit, wherein recorded temperature measurement values are compared to a specified target value for the temperature and wherein in the event of a deviation from the target value, the temperature or temperature distribution is controlled in an open- or closed-loop manner towards the target value.

### CROSS REFERENCE

This application is a national stage entry application under 35 U.S.C. 371 of PCT Patent Application No. PCT/DE2023/200157 filed on 27 Jun. 2023, which claims priority to German Patent Application No. 10 2022 207 939.6, filed on 1 Aug. 2022 the entire contents of each of which are incorporated herein by reference.

### FIELD

The present disclosure relates to an integrated circuit for signal processing of a sensor, wherein the sensor is an inductively working sensor or an eddy current sensor and wherein the circuit has electronic components and is part of an oscillating circuit.

Furthermore, the present disclosure relates to a method for the closed-or open-loop controlling of a temperature or of a temperature distribution in the circuit or in at least one electronic component of the circuit.

### BACKGROUND

An integrated circuit (IC) is, for example, a circuit that is implemented in semiconductor material—usually silicon—and, through a very high level of integration, realizes a circuit in a very small space, usually a few square millimeters.

There are numerous integrated circuits—ICs—available on the market for different measurement applications, including for controlling sensors using a complex resistance (impedance). Examples of sensors of this kind are inductive sensors or eddy current sensors, which are also used for measuring position or distance, among others. In this process, the impedance is assessed, which is influenced by the physical quantity to be measured, for example the distance or position of the measured object relative to the sensor.

The impedance measurement can be carried out using a oscillating circuit, wherein the sensor itself is a component of the oscillating circuit—or, to be more precise, the impedance of the sensor is part of the total impedance of the oscillating circuit. The oscillating circuit is part of a control and assessment circuit that either works as a free-running oscillator or contains a fixed oscillator. The frequency, amplitude or phase of the oscillation can be assessed.

However, in addition to the actual measured variable, there may also be various disturbances that influence the oscillation. This particularly includes temperature changes that not only affect the measured variable itself, but also the components of the oscillating circuit's circuitry, such as resistors, capacities or inductivities, or components of the assessment circuitry, such as oscillators, demodulators, amplifiers, filters, etc.

A change in temperature may change the values of the parameters that determine the oscillation, such as resistance, inductance or capacitance. This may distort the actual measurement signal and thus simulate a change in the physical quantity to be measured.

For example, in the case of eddy current sensors, detuning the oscillating circuit causes a change in the sensor signal, which would simulate a change in the distance.

For the signal stability of an eddy current sensor, for example, it is essential that a detuning of the oscillating circuit is not caused by disturbances, e.g. by a fluctuation in the ambient temperature. This would lead to misinterpretations and be interpreted as a change in distance. For discrete circuits, this influence can be reduced by using suitable components, e.g. capacities and resistances with low temperature coefficients, low tolerances, high quality and suitable capacity types for the application (X5R, X7R, COG).

Integrated circuits (ICs) are frequently used in modern, highly integrated, compact measuring systems, in particular application-specific ICs (ASICs). The very compact design and—for large quantities—the lower price are of advantage there. The capacities and resistances used in ICs or ASICs are subject to the technological tolerances and temperature coefficients of the CMOS technology in the semiconductor industry. These are usually higher than for discrete components and cannot be changed, e.g. by the adaptation of the technology; such changes are excluded in the CMOS semiconductor industry with stable processes.

It is therefore desirable to design an integrated circuit or integrated circuitry that forms a highly integrated but extremely temperature-stable part of an assessment circuit for sensors with complex resistance.

### SUMMARY

The present disclosure is therefore generally based on the objective of specifying a circuit and a method of the type mentioned at the beginning, whereby particularly precise measurements are possible even at changing temperatures with structurally simple means.

According to the present disclosure, above objective is accomplished, in an embodiment, by means of an integrated circuit having the features of claim 1 and, in an embodiment, by means of a method having the features of claim 12.

Accordingly, the integrated circuit according to claim 1 is characterized by a temperature-control device for the open- or closed-loop controlling of a temperature and/or of a temperature distribution in the circuit and/or in at least one electronic component of the circuit.

According to the method according to claim 12, recorded temperature measurement values are compared to a specified target temperature value and, in the event of a deviation from the target value, the temperature and/or temperature distribution is controlled in an open- or closed-loop manner towards the target value.

In accordance with the present disclosure, it has first been recognized that by cleverly equipping the circuit, the above-mentioned objective can be achieved in a surprisingly simple manner. For this purpose and further in accordance with the present disclosure, the circuit specifically features a temperature-control device designed for open- or closed-loop controlling of a temperature and/or of a temperature distribution in the circuit and/or in at least one electronic component of the circuit. With a temperature-control device of this kind, open- or closed-loop controlling of a temperature and/or temperature distribution in the circuit becomes possible, for example in the entire circuit or in a predefined part of the circuit, on the one hand, and a temperature and/or temperature distribution in one or more electronic components of the circuit on the other hand. This type of individual and component-sensitive open- or closed-loop controlling of a temperature and/or temperature distribution enables particularly individual compensation or minimization of temperature influences on the circuit.

Consequently, the integrated circuit according to the present disclosure and the method according to the present disclosure provide a circuit and a method that enable particularly accurate measurements, even at changing temperatures, with simple design means.

In an embodiment, the sensor may have a complex resistance (impedance).

The temperature-control device may have at least one temperature sensor if the circuit is designed in an manner that is favorable from an economic point of view. Depending on the application, one or more temperature sensors can be arranged at different positions in the circuit or on the carrier in order to reliably monitor temperature-critical areas in particular.

In order to achieve a particularly accurate measurement, at least one temperature sensor can be arranged in the area of or on one or more of the electronic components. In this way, at least one temperature sensor can be arranged on different pre-defined electronic components to provide particularly comprehensive temperature monitoring.

To maintain a specified temperature range or a specified temperature value, the temperature measurement values recorded by at least one temperature sensor can be compared with a specified target value or specified target values for the temperature using an assessment device. Suitable for open- or closed-loop control signals can be provided and output in a suitable manner via the assessment device.

In order to ensure safe open- or closed-loop controlling of a temperature and particularly precise measurements, the temperature-control device can have at least one heating element, for example a resistor or a transistor, and/or at least one cooling element, for example a Peltier element. A heating element and/or cooling element of this type can receive open- or closed loop control signals provided by the assessment unit in order to ensure safe open- or closed-loop controlling of a temperature and/or a temperature distribution.

Furthermore, with a view to a particularly accurate measurement and the open- or closed-loop controlling of a temperature and/or temperature distribution, the at least one heating element and/or the at least one cooling element can be arranged in the area of or on one or more of the electronic components. The specific arrangement of heating and/or cooling elements can be customized for each application and the specific design of the circuit with its electronic components, in order to meet a variety of practical requirements.

Likewise with regard to a particularly precise measurement with a sensor, one or more of the electronic components can be designed as one or more integrated or external capacities for setting an operating point of the oscillating circuit, which can be connected to the oscillating circuit and disconnected from the oscillating circuit by means of a switching device.

In an embodiment, the switching device can have a single switch for each capacity and/or be integrated into the circuit and/or be controllable via a digital interface. This enables a customized adaptation of the circuit to different requirements and sensors. In a further design, a separate interface of this type can be provided in particular for each individual switch.

Furthermore, for particularly precise measurements, the temperature-control device can be used for an open- or closed-loop controlling of the temperature or temperature distribution of one or more components outside the circuit.

In an embodiment, the component or components arranged outside the circuit may be one or more external capacities for adjusting the operating point of the oscillating circuit.

In the following, aspects and advantages of embodiments of the integrated circuit according to the present disclosure and the method for an open- or closed-loop controlling of a temperature or a temperature distribution in such a circuit or in at least one electronic component of the circuit will be explained:

An embodiment of the integrated circuit according to the present disclosure—referred to in this document as an IC or chip—can be manufactured using the methods known in semiconductor technology. It may have one or more integrated capacities that can be added to or disconnected from the oscillating circuit electronically via the integrated switches. These capacities influence the oscillating circuit and serve to adjust the operating point for the oscillating circuit. The integrated switches can be controlled via an interface, for example, via a digital interface of the IC. However, an analog interface is also possible. A sensor can then be easily adjusted via the interface, for example, in a partially automated or automated process, by compensating for the production-related tolerances of the sensor and/or all components in the oscillating circuit and carrying out the desired tuning of the oscillating circuit.

Furthermore, the IC can also contain other circuit components of the control and assessment circuit. These include, for example, one or more oscillators, demodulators, amplifiers or filters. Ideally, the IC contains all the circuit components required to control and assess the sensor, which allows for a very compact and robust design. It is advantageous for the IC to contain digital circuit elements in addition to the purely analog circuit parts, i.e. for it to be a so-called “mixed signal” IC. Digital circuit parts can be, for example, AD converters (analog-digital converters), digital controllers, computer cores, digital interfaces, memory areas or other usual components required for digital signal processing.

Temperature changes in such mixed signal ICs primarily affect the analog circuit components. Digital circuit components are hardly affected, because digital signals consist of a sequence of the logic states 0 or 1. The signal levels of logic states, for example 0 V (logical “0”) and 3.3 V (logical “1”), may be subject to a wider range of fluctuation. However, in the case of analog signals, the smallest changes, for example in the millivolt range, which occur due to disturbances such as temperature, have a significant effect on the signal quality. In particular, capacities are subject to major changes due to changing temperatures. These temperature changes can be caused not only by the ambient temperature acting from outside, but also by the circuit components contained in the IC, which produce heat loss. These temperature effects can be reduced in accordance with the present disclosure by for open- or closed-loop controlling of the temperature and/or temperature distribution of the IC.

For this purpose, one or more heating elements can be arranged at certain positions on the chip, which are used for controlled heating of the IC. The heating elements can be temperature-adjustable resistors that are manufactured using conventional semiconductor processes, for example in CMOS technology. The current flowing through the heating element is used as a control variable here. But other heating elements are also conceivable, for example a transistor that heats up due to the current flow, or other components that can be produced in conventional semiconductor processes and that produce heat loss in a controlled manner. The actual temperature of the IC, which can be measured with one or more temperature sensors on the chip, is used as the control variable for temperature control.

A temperature sensor can also be arranged on the chip, which determines the current temperature of the chip and outputs a temperature signal, for example a preferably calibrated voltage. Temperature sensors that can be produced using conventional semiconductor processes can be used as temperature sensors. The target temperature that the chip is to reach through the heating elements can be set electronically via an interface. It makes sense for the IC to also include a circuit for temperature control. In this part of the circuit, the current temperature is compared with the target value. The target value can be specified digitally, for example, via a register. This allows the target temperature in the IC, for example, to be set from approx. 30 to 70° C. in 2.5° C. steps via a digital interface. Alternatively, an external signal could be applied to a housing pin of the IC, for example via a resistor, which then sets the target temperature. In a case such as this, the temperature is hardwired to the circuit board and cannot be specified electronically. However, it is also possible to specify an external target value via an analog interface, for example a current or voltage value. If the current temperature is below the target value, the electronics regulate the heating element(s), causing them to heat up. If the target temperature is exceeded, the temperature is reduced or the system is cooled. In steady state, the target temperature is maintained. Depending on the heating element used, the control can be regulated by means of the current, the voltage or digitally.

Initially, the temperature of the internal capacities, which are particularly dependent on temperature changes, can be regulated using the heating elements. However, it is beneficial when not only the capacities, but the entire circuit is thermalized. In discrete circuits, the entire circuit—including the clock divider, coils, drivers, assessment, and summation and differentiation—is exposed to the ambient temperature, which makes temperature control difficult or impossible. In the IC according to the present disclosure, on the other hand, all circuit components can be kept at a constant temperature. In addition, the external components outside the IC, for example external capacities for further adjustment of the oscillating circuit, can also be stabilized because the IC also transfers heat to the surrounding components on the circuit board to which it can be soldered.

This is why fluctuations in the ambient temperature do not affect the temperature-controlled circuit in the IC, and thus the entire assessment circuit. In addition, changes in ambient temperature have less effect on the external capacities because these are placed on the printed circuit board in the immediate vicinity of the IC. This will help to stabilize the high external capacities to some extent. To improve the control characteristics, it may be useful to install one or more temperature sensors in the vicinity of the external capacities.

In an exemplary embodiment, with a change in the ambient temperature of 10° C. with the aid of the temperature stabilization according to the present disclosure, the temperature of the circuit parts in the IC changes by a maximum of 0.3° C. The temperature of the external capacities, which are arranged on the circuit board near the IC, changes by only about 3° C. In contrast, if the circuit were discrete, the entire circuit would be exposed to the full temperature change of 10° C.

Initially, different temperature levels in the IC are not crucial for the correct functioning of the assessment circuit. The relative temperature of circuit parts to each other, in particular the capacities of the oscillating circuit to each other, is usually not relevant for stable functioning, since only the ratio of these parts to each other is important. Only the absolute temperature must be constant, since differences can be calibrated.

In special cases, however, it may be useful to control the relative temperature change of the components on the IC. To do this, several temperature sensors could be distributed across the chip instead of just one. This would also allow targeted open- or closed-loop controlling of a temperature distribution on the chip, or the temperature at different locations on the chip could be used for control for different operating states.

The stabilized temperature of the integrated circuit stabilizes the value of the internal capacities used to adjust the operating point of the oscillating circuit. But other parts of the circuit, whose stability is crucial for the control or assessment of the sensor, can also be stabilized with it. These include, for example, resistors within the RC element of the oscillating circuit. Furthermore, other components and elements within the measuring chain that determine accuracy, such as the oscillator, demodulator, driver, amplifier, etc., can be stabilized. This active temperature control reduces fluctuations in the chip temperature caused by external influences-ambient temperature-and achieves long-term stabilization of the operating point.

A concrete embodiment may be an integrated circuit for the signal processing of a sensor with a complex resistance, which is a component of a oscillating circuit and contains one or more capacities, resistances, an RC element and/or other components, for example within a measuring chain, which can preferably be switched preferably via an interface. The integrated circuit has at least one temperature sensor and at least one heating element, which are used to control the temperature and/or temperature distribution of the integrated circuit.

The heating element(s) or temperature sensor(s) can be arranged on or near the internal capacities.

The temperature of the capacities can be regulated using temperature sensors and heating and/or cooling elements.

The temperature distribution can be controlled or kept constant within the circuit.

The integrated circuit may contain one or more capacities that can be connected to the oscillating circuit to change the oscillating circuit's operating point.

In one embodiment of the method according to the present disclosure, the signals of the temperature sensors can be compared with a target value for the temperature.

Furthermore, the temperature deviation can be used to adjust heating and/or cooling elements to stabilize the chip temperature.

In further embodiments, the sensor can be arranged separately from the integrated circuit, wherein the sensor itself is not temperature-controlled.

In further embodiments, an additional heating and/or cooling element is used to control the temperature, which otherwise has no function whatsoever within the circuit or the switching circuit and is used exclusively for heating and/or cooling. In particular, such a heating and/or cooling device is not part of the sensor's assessment circuit. This has the advantage that the temperature control can be realized independently of the other functions of the circuit. In very basic terms, such a heating element can be, for example, a passive resistor, or an active transistor, or such a cooling element can be, for example, a passive Peltier element.

In further embodiments, a coil is part of an oscillating circuit. In this case, the components determining the oscillating circuit besides the coil, namely capacitors or resistors of an RC element, can be kept at a constant temperature. A temperature change of the RC element would have an effect on the measuring signal and would falsify it. This is effectively suppressed by the temperature control. Furthermore, other determining components within the measuring chain, such as oscillators, demodulators, drivers, amplifiers, etc., can be temperature-stabilized as an alternative or in addition.

There are then various possibilities for advantageously designing and refining the teaching of the present present disclosure. For this purpose, reference is made to the subordinate claims and the following explanation of exemplary embodiments of the circuit and method according to the present disclosure, based on the drawing. In connection with the explanation of the exemplary embodiments of with reference to drawings, embodiments and refinements of the teachings are also explained in general.

### BRIEF DESCRIPTION OF THE DRAWINGS

FIG. 1 shows a schematic diagram of an embodiment of the integrated circuit according to the present disclosure;

FIG. 2 shows a schematic diagram of another embodiment of the integrated circuit according to the present disclosure;

FIG. 3 shows a schematic diagram of yet another embodiment of the integrated circuit according to the present disclosure.

### DETAILED DESCRIPTION OF THE DISCLOSURE

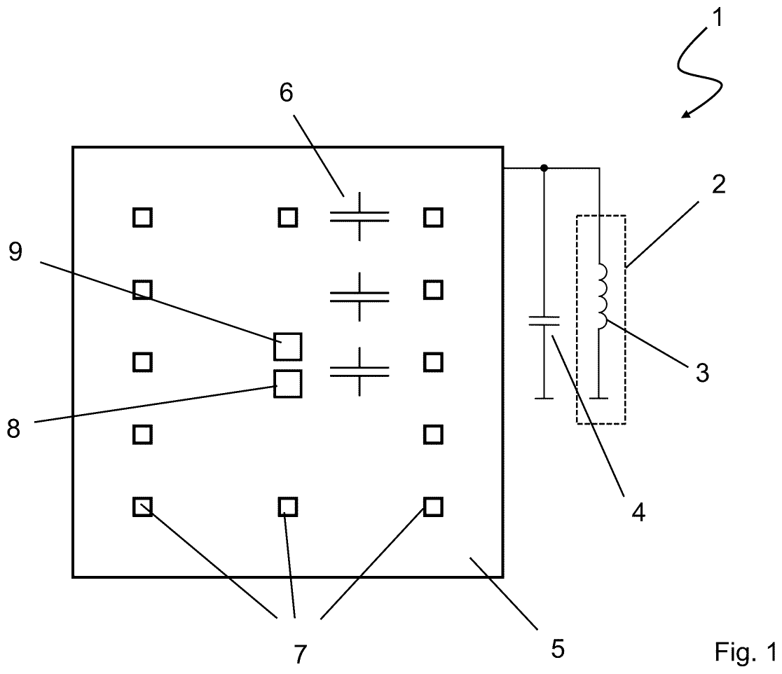

FIG. 1 shows a schematic diagram of an embodiment of the integrated circuit according to the present disclosure with an assessment circuit 1 for an inductive or eddy current sensor 2, hereinafter referred to as sensor, which contains a coil 3 as a sensitive element. Such sensors 2 can be used to detect distances to a metallic measurement object (not shown). The assessment circuit 1 contains a oscillating circuit consisting of the inductance L of the coil 3, a first parallel capacity 4 and the IC 5 according to the present disclosure with internal capacities 6. Furthermore, the IC 5 contains heating elements 7, a temperature sensor 8 and a temperature control 9, wherein not all heating elements 7 are provided with reference signs in FIG. 1 for reasons of clarity, but can be identified as such on the basis of the uniform size and distribution over the chip surface. The internal capacaties 6 are located on the silicon chip 5 and can be electronically connected to or separated from the oscillating circuit. In this variant, the actual temperature of the IC 5 is measured centrally with a temperature sensor 8 and the temperature control 9 regulates a heating current that is distributed to all heating elements 7 with the help of current mirrors. This variant is suitable for ICs 5 in which the self-heating of the chip 5 is homogeneous and the temperature gradient across the chip 5 without heating elements 7 is small.

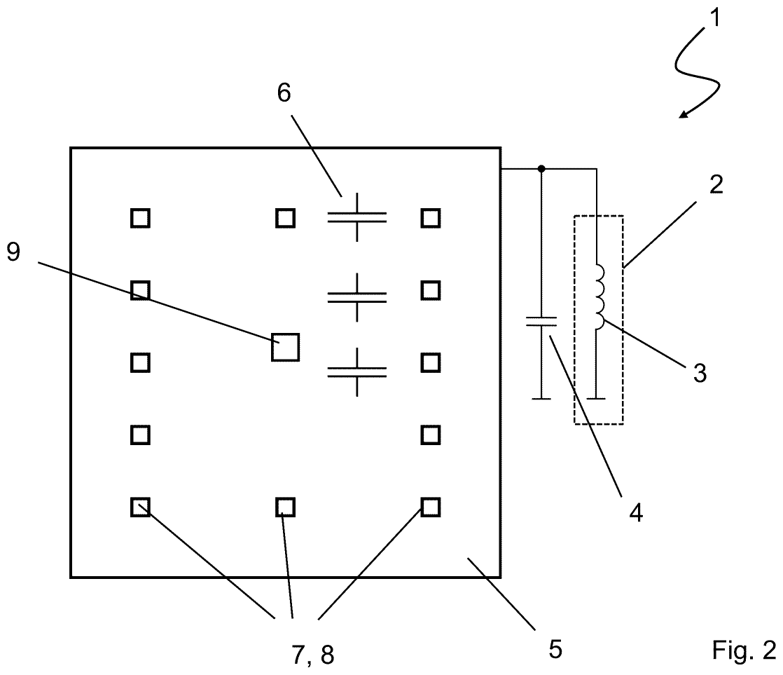

FIG. 2 basically shows the assessment circuit 1 from FIG. 1, but an IC 5 with heating elements 7, in each of which a temperature sensor 8 is integrated. The internal capacities 6 are located on the chip 5 and can be electronically connected to or disconnected from the oscillating circuit. The temperature sensors 8 of the heating elements 7 can be used to measure the local temperature of the silicon chip 5, and the temperature control 9 can individually control the heating power of the heating elements 7. This variant is particularly suitable for chips 5, where the self-heating of the silicon is highly inhomogeneous. The heating elements 7 can be used to reduce inhomogeneity and decrease the temperature gradient across the chip 5.

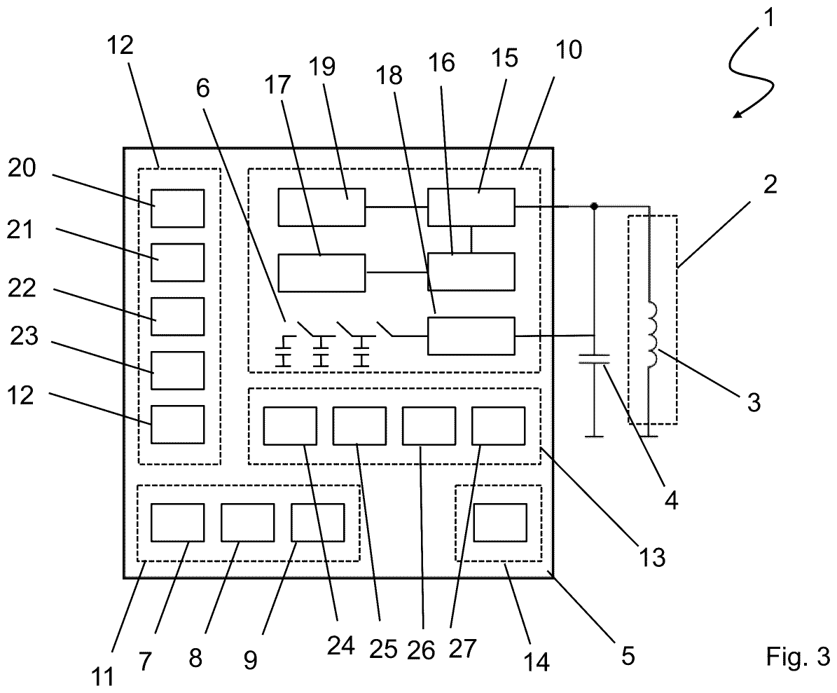

FIG. 3 shows a more detailed assessment circuit 1 with additional functional elements: In addition to the sensor 2 with the coil 3 and the external parallel capacity 4, the integrated circuit 5 contains the higher-level functional units 10, 11, 12, 13, 14 for sensor control and assessment 10, temperature stabilization 11, power supply 12, the digital part 13 and a test module 14.

To control sensor 2 and assess the signal, functional unit 10 contains a driver 15 to energize coil 3 with alternating current, a demodulator 16 to demodulate the signal, and a preamplifier or amplifier 17 to amplify the signal. In addition, a switch 18 is included that can be used to switch further internal capacities 6 on or off in addition to the external parallel capacity 4. This makes it possible to adjust sensor 2 so that it is operated at its optimum operating point. The oscillator for controlling the oscillating circuit could be arranged externally on the printed circuit board, or also in the functional unit 10 as an integrated oscillator 19.

The functional unit 11 for temperature stabilization consists of the heating elements 7, the temperature sensor(s) 8 and the temperature control 9.

The functional unit for the power supply 12 contains a power-on reset 20, one or more voltage regulators 21 for generating and stabilizing internal supply voltages for analog and digital functional units, driver stages for direct current 22, constant current sources (bias) 23 as a reference current source for special functional units, for example to generate reference currents for the temperature sensor(s) 8.

Functional unit 13 for the digital part contains a digital interface 24, e.g. SPI, and an EPROM 25. A computer core, e.g. a microcontroller 26, could also be integrated in the digital part, for example to control function blocks in the IC, or an analog-digital converter 27 to convert the analog sensor signal into a digital signal.

A test module 14 is also included for testing purposes.

To avoid repetitions with regard to further advantageous embodiments of the device according to the present disclosure as well as the method according to the present disclosure, reference is made to the general part of the description and to the appended claims.

Finally, it is to be expressly noted that the above-described exemplary embodiments are used solely to explain the claimed teaching, but does not restrict it to the exemplary embodiments.

List of reference numerals

| | |
|---|---|
| 1 | assessment circuit, assessment device |
| 2 | sensor |
| 3 | Coil |
| 4 | parallel capacity |
| 5 | IC |
| 6 | Internal capacity |
| 7 | heating element |
| 8 | temperature sensor |
| 9 | temperature control |
| 10 | sensor control and assessment |
| 11 | temperature stabilization |
| 12 | power supply |
| 13 | digital part |
| 14 | test module |
| 15 | driver |
| 16 | demodulator |
| 17 | preamplifier or amplifier |
| 18 | Switch |
| 19 | oscillator |
| 20 | power-on reset |
| 21 | voltage regulator |
| 22 | driver stage for direct current |
| 23 | constant current source (bias) |
| 24 | digital interface |
| 25 | EPROM |
| 26 | microcontroller |
| 27 | Analog/digital converter |

1. An integrated circuit for signal processing of a sensor, wherein the sensor is an inductively working sensor or an eddy current sensor and wherein the circuit has electronic components and is part of an oscillating circuit, comprising:
a temperature-control device for the open- or closed-loop controlling of a temperature and/or of a temperature distribution in the circuit and/or in at least one electronic component of the circuit.

2. The integrated circuit according to claim 1, wherein the sensor has a complex resistance.

3. The integrated circuit according to claim 1, wherein the temperature-control device has at least one temperature sensor.

4. The integrated circuit according to claim 3, wherein the at least one temperature sensor is arranged in the area of one or more of the electronic components or on one or more of the electronic components.

5. The integrated circuit according to claim 3, wherein the temperature measurement values recorded by means of the at least one temperature sensor are comparable with a specified target value for the temperature by means of an assessment device.

6. The integrated circuit according to claim 1, wherein the temperature-control device has at least at least one of: at least one heating element and/or and at least one cooling element.

7. The integrated circuit according to claim 6, wherein the at least one heating element and/or the at least one cooling element are arranged in the area of one or more of the electronic components or on one or more of the electronic components.

8. The integrated circuit according to claim 1, wherein in order to set an operating point of the oscillating circuit, one or more of the electronic components are configured as one or more integrated or external capacities which can be connected to the oscillating circuit and disconnected from the oscillating circuit by means of a switching device.

9. The integrated circuit according to claim 8, wherein the switching device is at least one of: an individual switch for each capacity; integrated into the switching circuit; can be activated via a digital interface; and, has a separate interface for each individual switch.

10. The integrated circuit according to claim 1, wherein by means of the temperature-control device one or more components arranged outside the circuit can be controlled in an open or closed-loop manner with regard to their temperature or temperature distribution.

11. The integrated circuit according to claim 10, wherein the component or components arranged outside the circuit are one or more external capacities for setting the operating point of the oscillating circuit.

12. A method for the open or closed-loop controlling of a temperature or of a temperature distribution in the circuit or in at least one electronic component of the circuit with a circuit according to claim 1, wherein recorded temperature measurement values are compared to a specified target value for the temperature and wherein in the event of a deviation from the target value, the temperature or temperature distribution is controlled in an open- or closed-loop manner towards the target value.
